(19) United States
(12) Patent Application Publication
(10) Pub. No.: US 2026/0211013 A1
(43) Pub. Date: Jul. 23, 2026

(54) CURRENT DETECTION ARRANGEMENT FOR ELECTRIC GRIDS

(71) Applicant: ABB S.p.A., Milano (IT)

(72) Inventors: Gioele Gregis, San Paolo D'argon (IT); Andres Enrique Villamil Prieto, Bergamo (IT)

(21) Appl. No.: 19/416,138

(22) Filed: Dec. 11, 2025

(30) Foreign Application Priority Data
Jan. 23, 2025 (EP) 25153461.6

(51) Int. Cl. G01R 19/165; G01R 15/18; G01R 15/20; G01R 19/15; G01R 31/40; G01R 31/58

(52) U.S. Cl. CPC G01R 19/16538; G01R 15/181; G01R 15/202; G01R 19/15; G01R 31/40; G01R 31/58

(57) ABSTRACT

A detection arrangement for DC grids is provided. The arrangement includes a first detection module configured to measure a line current flowing along an electric line and to generate a first detection signal indicative of said current. The arrangement also includes a second detection module that is configured to detect the same line current and to generate a second detection signal indicative of the time-dependent rate of change of the current magnitude. The arrangement further comprises multiple signal processing modules designed to process the first and second detection signals and to generate an output signal indicative of the behavior of the line current.

### CROSS-REFERENCE TO RELATED APPLICATIONS

This application claims priority to European Patent Application No. 25153461.6 filed on Jan. 23, 2025, and titled “A CURRENT DETECTION ARRANGEMENT FOR ELECTRIC GRIDS”, the entire contents of which are hereby incorporated by reference.

### TECHNICAL FIELD

The present disclosure relates to the field of electric grids. More particularly, the present disclosure relates to a current detection arrangement for electric grids, which provides improved functionalities and greatly favors the implementation of fast disconnection procedures of portions of electric grid in case of fault events.

### BACKGROUND

As known, when a fault event (such as a short-circuit) occurs in an electric line, many electrical components electrically connected to the electric line can feed such an electric fault. This may lead to catastrophic consequences, particularly when electric power generation systems (for example, photovoltaic panels) or electric energy storage systems (for example, batteries) are installed.

To prevent such an eventuality, an electric grid normally comprises protection devices configured in such a way to disconnect electric grid portions, whenever necessary. Typically, these protection devices include solid-state switches as these latter generally ensure a shorter switching time in comparison to electro-mechanical switches.

Normally, a protection device intervenes to interrupt an electric line upon receiving a trip signal provided by a suitable IED (Intelligent Electronic Device), for example a protection relay, operatively coupled to or included in the protection device. In turn, the above-mentioned IED includes or is operatively coupled to a current detection arrangement to monitor the behavior of the line current flowing along the electric line.

As it is known, in modern electric grids, a current flowing along an electric line may be subject to sudden and strong raises (even in the order of thousands A/ms) when an electric fault (for example, a short-circuit) occurs. Typically, line currents of this type may cause relevant damage to the electric loads fed by the electric line and to the solid-state switches included in a protection device operatively coupled to the electric line.

In view of the above, the market strongly requires that protection devices intervene to interrupt electric lines as quickly as possible and with high levels of accuracy to ensure a reliable circuit protection and, at the same time, prevent unnecessary service interruptions. Unfortunately, this objective is difficult to achieve, nowadays. In fact, detection arrangements currently employed in electric grids offer poor detection performances when line currents vary so fast.

In the state of the art, it is therefore still quite felt the need for innovative solutions, which allow a fast and reliable detection of currents in electric lines and are relatively simple and inexpensive to produce at industrial level.

### BRIEF DESCRIPTION

In order to respond to this need, the present disclosure provides a current detection arrangement for electric grids, according to the following embodiments.

### BRIEF DESCRIPTION OF DRAWINGS

General characteristics and advantages of the present disclosure will become apparent from the detailed description of exemplary embodiments of the disclosure, which is illustrated only by way of non-limitative examples in the accompanying drawings, wherein:

FIG. 1 shows a block diagram of current detection arrangement, according to a general embodiment of the present disclosure;

FIG. 1A shows a block diagram of current detection arrangement, according to another embodiment the present disclosure;

FIG. 2 is a block diagram showing an example of intelligent electronic device including a current detection arrangement, according to the present disclosure;

FIG. 3 is a block diagram showing an example of intelligent electronic device operatively coupled to a current detection arrangement, according to the present disclosure;

FIGS. 4-7 schematically show the operation of the current detection arrangement, according to the present disclosure;

FIGS. 8-10 schematically show some examples of tripping curves set by an electronic device employing the current detection arrangement, according to the present disclosure, to command a protection device operatively associated thereto.

With reference to the cited figures, the present disclosure relates to a current detection arrangement 1 for electric grids operating at low-voltage or medium-voltage levels.

### DETAILED DESCRIPTION

Within the framework of the present disclosure, the term “low voltage” relates to operational voltages up to 1.5 kV DC (which may be extended even to 3 kV in certain applications) whereas the term “medium voltage” generally relates to operational voltages higher than 1.5 kV DC (or 3 kV in certain applications) up to several tens of kV, for example up to 100 kV DC.

The current detection arrangement 1 of the present disclosure is particularly adapted for use in DC electric grids and it will be described in the following with particular reference to these applications without intention of limiting the scope of the disclosure in any way. The current detection arrangement 1 of the present disclosure, in fact, may be advantageously used in AC electric grids.

In operation, the current detection arrangement 1 is operatively coupled to an electric line 100 (such as a DC electric line) of an electric grid and is capable of providing improved detection functionalities of a line current I flowing along said electric line.

The electric line 100 may be arranged according to solutions of known type. Therefore, in the following, the electric line 100 will be described only with reference to the aspects of the present disclosure for the sake of brevity.

As it will be apparent from the following description, the current detection arrangement 1 includes a plurality of detection modules 3, 4 and signal processing modules 5, 6, 7, 8, 9 configured to implement current detection functionalities. In some embodiments, these modules are implemented at industrial level in an analog manner. To this aim, each of the aforesaid modules can include electronic circuits (for example operational amplifying circuits) suitably designed to perform the foreseen functionalities. These electronic circuits may form stand-alone circuit units or be at least partially integrated one to another or in one or more circuit units. These electronic circuits may be realized on one or more printed circuit boards realized at industrial level through printed circuit manufacturing techniques of known type.

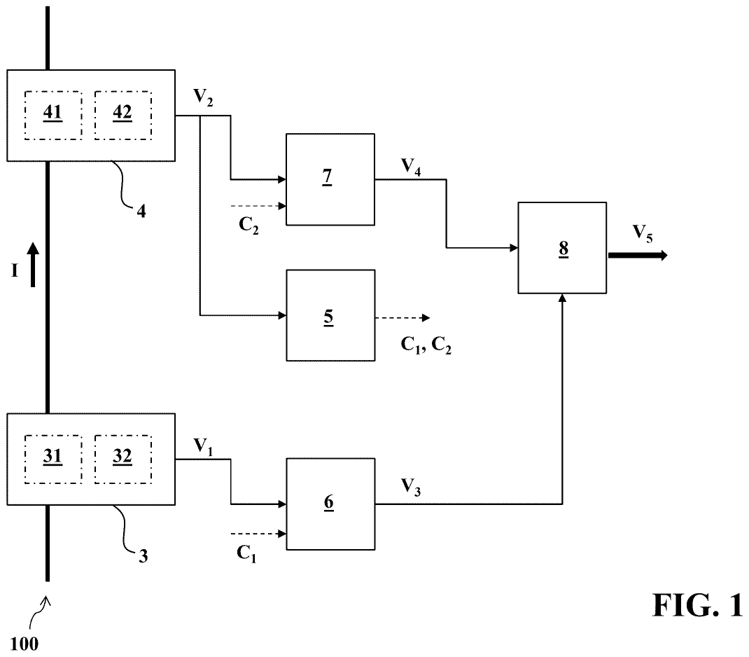

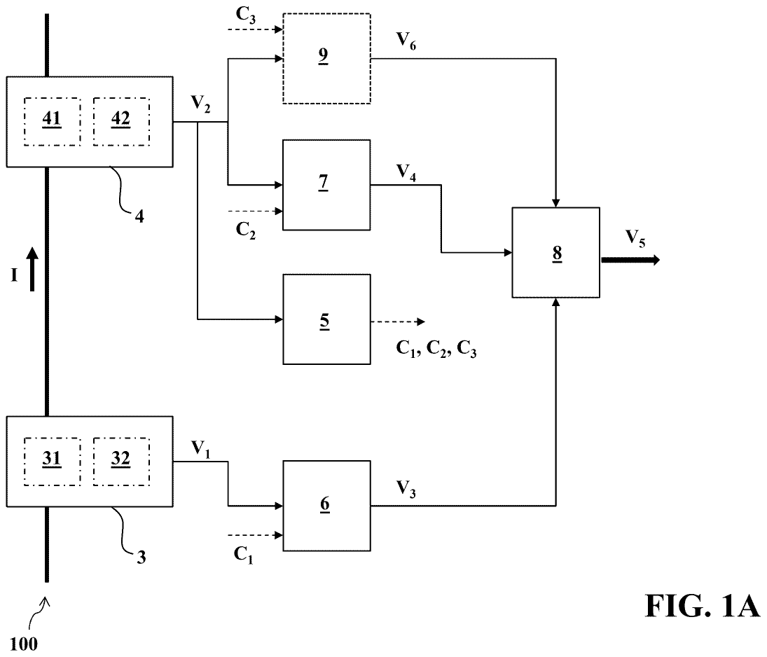

Reference is now made to FIG. 1 that shows the current detection arrangement 1 according to a general embodiment of the present disclosure. The current detection arrangement 1 comprises a first detection module 3 operatively coupled to the electric line 100, in use.

The first detection module is configured to detect a line current I, which flows along the electric line 100 and provides a first detection signal V₁ indicative of said line current. The first detection signal V₁ is a signal variable in time depending on the magnitude of the detected line current I. In practice, the first detection signal V₁ describes the behavior of the line current I over time.

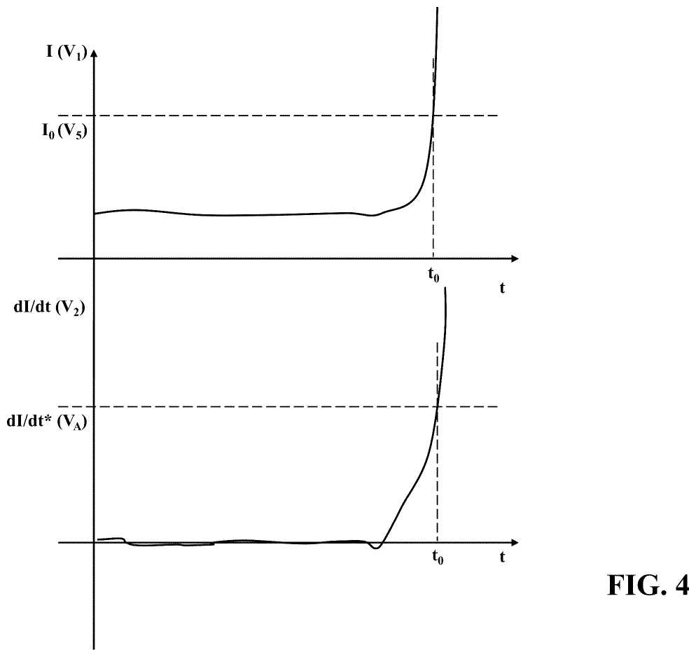

FIG. 4 schematically represents the behavior of the first detection signal V₁ as provided by the first detection module 1. As it is possible to notice, the first detection signal V₁ describes the behavior of the line current I (more precisely of the magnitude of the line current) over time.

As it will be more apparent from the following, the first detection signal V₁ provided by the first detection module 3 can follow the behavior of line current I only when the latter is subject to small or slow variations with respect to a nominal value.

In some embodiments, the first detection signal V₁ is a voltage signal in such a way to favor its processing by suitable signal processing resources 6, 8, 10 arranged in cascade to the first detection module.

In some embodiments, the first detection module 3 comprises a first sensing block 31 including one or more Hall-effect sensors or one or more shunt circuits operatively coupled to one or more conductors of the electric line 100 in a known manner.

The first sensing block 31 can include suitable electronic circuits (for example, operational amplifying circuits) to process (for example, amplify and/or combine) the output signals provided by the above-mentioned current sensors operatively coupled to the electric line.

In some embodiments, the first detection module 3 comprises a first filtering block 32 electrically connected in cascade to the first sensing block 31. The first filtering block 32 is conveniently configured to filter high-frequency spurious components of the output signal provided by the first sensing block 31. The first filtering block 32 can include suitable electronic circuits (for example, operational circuits) to implement a low pass filtering of the output signal provided by the first sensing block 31.

The current detection arrangement 1 comprises a second detection module 4 operatively coupled to the electric line 100. The second detection module 4 is configured to provide a second detection signal V₂ indicative of a variation rate dI/dt over time of the detected line current I. The second detection signal V₂ is a signal variable in time depending on the magnitude variation rate over time of the line current. In practice, the second detection signal V₂ is indicative of the derivative over time of the line current I (if the latter is considered as a time-variable function). As it will be more apparent from the following, the second detection signal V₂ provided by the second detection module 4 can be used to determine the rate of change of the current I even when the latter is subject to quick variations with respect to a nominal value.

FIG. 4 schematically represents the behavior of the second detection signal V₂ as provided by the second detection module 4. As it is possible to notice, the second detection signal V₂ is the derivative over time of the first detection signal V₁. Therefore, it describes the behavior of the variation rate dI/dt over time of the line current I.

In some embodiments, the second detection signal V₂ is a voltage signal in such a way to favor its processing by suitable signal processing resources 7, 8, 9, 10 arranged in cascade to the aforesaid second detection module 4.

In some embodiments, the second detection module 4 comprises a second sensing block 41 including a Rogowski coil operatively coupled to the one or more conductors of the electric line 100 in a known manner. The third sensing block 41 can include suitable electronic circuits (for example, operational circuits) to process (for example, amplify and/or combine) the output signal provided by the Rogowski coil operatively coupled to the electric line.

In some embodiments, the second detection module 4 comprises a second filtering block 42 electrically connected in cascade to the second sensing block 41. The second filtering block 42 is conveniently configured to filter high-frequency spurious components of the output signal received from the second sensing block 41. The second filtering block 42 can include suitable electronic circuits (for example, operational circuits) to implement a low pass filtering of the output signal provided by the second sensing block 41.

The current detection arrangement 1 comprises a first signal processing module 5 operatively coupled to the second detection module 4 to receive and process the second detection signal V₂. The first signal processing module 5 is configured to control the operation of other signal processing modules 6, 7, 9 depending on the operating conditions of the electric line 100, which are conveniently determined based on the second detection signal V₂. The first signal processing module 5 is configured to determine whether the electric line 100 operates in a normal condition or an abnormal condition based on the second detection signal V₂.

For the sake of clarity, it is specified that term “normal condition” refers to an operating condition of the electric line, in which there is a small detected variation or a slow variation of the line current I (more precisely of the magnitude thereof) compared to an expected nominal value. In this case, the electric line may be subject to no electric faults or to electric faults (for example, overloads) in which the line current I raises slowly (for example in the order of tens A/ms).

On the other hand, the term “abnormal condition” refers to an operating condition of the electric line, in which there is a relevant raising of the line current I detected (more precisely of the magnitude thereof) with respect to an expected nominal value. In this case, the electric line may be affected by electric faults (for example, short-circuits), in which the line current I raises quickly (for example in the order of thousands A/ms).

In some embodiments, in operation, the first signal processing module 5 compares the second detection signal V₂ with a first threshold value V_{A} indicative of a threshold variation rate dI/dt* set for the line current I (FIG. 4). The first threshold value V_{A} can be set depending on physical boundaries above which dangerous operating conditions are known to occur. Said boundaries are known for a given system and depend on several factors such as the characteristics of the electric line and the protection device, for example the equivalent inductance of the electric line, the turn off capability of the protection device, and the like.

In some embodiments, the first signal processing module 5 determines that the electric line 100 operates in a normal condition, if the second detection signal V₂ does not exceed the first threshold value V_{A}, and determines that the electric line 100 operates in an abnormal condition, if the second detection signal V₂ exceeds the first threshold value V_{A}. The first signal processing module 5 is configured to provide control signals C₁, C₂, C₃ to control the operation of other signal processing modules 6, 7, 9. These control signals are conveniently generated depending on the operating conditions of the electric line 100 as determined by the first signal processing module 5. The above-mentioned control signals are thus indicative of the operating conditions of the electric line 100. The deliver of the control signals C₁, C₂, C₃ by the first signal processing module 5 may occur according to several modes, according to the needs.

As an example, the control signals C₁, C₂, C₃ can be logic signals taking a low value (for example, ≈0V), if the electric line 100 is determined to operate in a normal condition, and a high value (for example, ≈3.3V), if the electric line 100 is determined to operate in an abnormal condition, or vice-versa.

As a further example, the first signal processing module 5 can send no control signals if the electric line 100 is determined to operate in a normal condition, and send a certain control signal C₁, C₂, C₃ (trigger signal) at a trigger instant t₀, when the electric line 100 is determined to operate in an abnormal condition (namely, when a relevant rising of the magnitude of the line current is detected).

As a further example, the first signal processing module 5 can send a certain control signal C₁, C₂, C₃ (enabling signal) if the electric line 100 is determined to operate in a normal condition and stop sending such a control signal at a trigger instant t₀, when the electric line 100 is determined to operate in an abnormal condition. The first signal processing module 5 may be easily designed to generate the control signals C₁, C₂, C₃ according to further alternative modes upon the determination of the operating conditions of the electric line 100.

The current detection arrangement 1 comprises a second signal processing module 6 operatively coupled to the first detection module 3 to receive and process the first detection signal V₁. The second signal processing module 6 is configured to provide and output a third detection signal V₃, which is generated based on the first detection signal V₁.

In some embodiments, the third detection signal V₃ is a voltage signal in such a way to favor its processing by suitable signal processing resources 8, 10 arranged in cascade to the aforesaid second signal processing module.

The second signal processing module 6 is configured to provide a third detection signal V₃, which substantially tracks the first detection signal V₁ received from the first detection module 3, if a normal operating condition of the electric line 100 is determined by the first signal processing module 5. In this case, the third detection signal V₃ is a signal variable in time depending on the magnitude of the line current I. In practice, the third detection signal V₃ is indicative of the line current I over time (as the first detection signal V₁).

The second signal processing module 6 is configured to provide a third detection signal V₃, which takes a constant value V_{S}, if an abnormal operating condition of the electric line 100 is determined by the first signal processing module 5. In this case, the third detection signal V₃ is constant in time and takes a constant value V_{S} indicative of a magnitude value I₀ of the line current I measured by the first detection module 3 at a trigger instant t₀, at which the first signal processing module 5 has determined that the electric line 100 operates in an abnormal condition.

The second signal processing module 6 is apparently configured to carry out signal track and hold functionalities depending on the operating conditions of the electric line 100, as determined by the first signal processing module 5. The second signal processing module 6 carries out track functionalities if a normal condition of the electric line is determined by the first signal processing module 5 (namely, before the trigger instant t₀). In this case, the third detection signal V₃ substantially tracks the first detection signal V₁.

The second signal processing module 6 carries out hold functionalities if an abnormal condition of the electric line is determined by the first signal processing module 5 (namely, after the trigger instant t₀). In this case, the third detection signal V₃ takes the constant value V_{S}, which is taken by the first detection signal V₁ at the trigger instant t₀. Advantageously, the second signal processing module 6 operates based on first control signals C₁ received from the first signal processing module 5.

As an example, the second signal processing module 6 can carry out the above-mentioned tracking functionalities, if it has not received any control signal from the first signal processing module 5, and can carry out the above-mentioned hold functionalities in response to receiving a control signal C₁ (trigger signal) indicating that the first signal processing module 5 has determined that the electric line 100 operates in an abnormal condition (trigger instant t₀, possible transmission delays are substantially negligible).

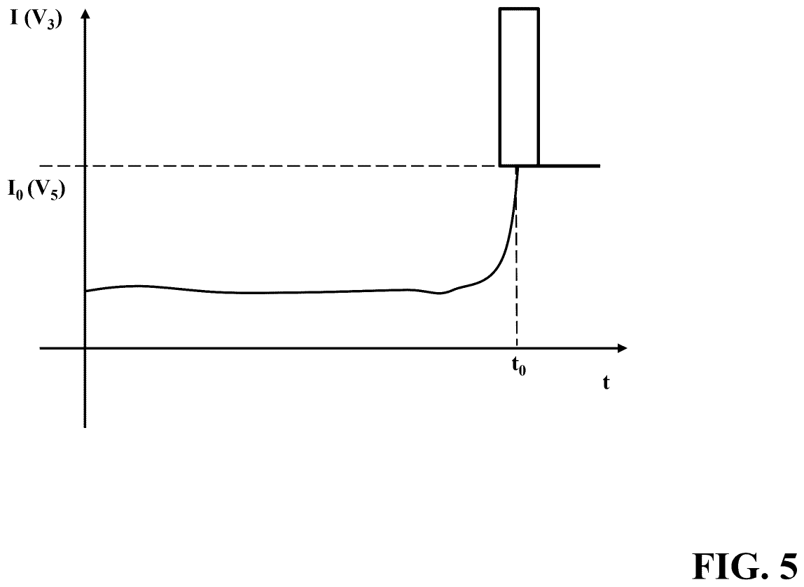

FIG. 5 schematically represents the behavior of the third detection signal V₃ as provided by the second signal processing module 6. As it is possible to notice, the third detection signal V₃ substantially follows the first detection signal V₁ (namely, the magnitude of the line current I) at time instants preceding the trigger instant t₀ and takes a constant value V_{S} (which is indicative of the magnitude value I₀ of the line current I measured by the first detection module 3 at the trigger instant t₀) at time instants following the trigger instant t₀.

The detection arrangement 1 comprises a third signal processing module 7 operatively coupled to the second detection module 4 to receive and process the second detection signal V₂. The third signal processing module 7 is configured to provide and output a fourth detection signal V₄, which is generated based on the second detection signal V₂.

In some embodiments, the fourth detection signal V₄ is a voltage signal to favor its processing by suitable signal processing resources 8, 10 arranged in cascade to the third signal processing module 7. The third signal processing module 7 is configured to provide no detection signals (or a null detection signal), if a normal condition of the electric line 100 is determined by the first signal processing module 5. In practice, if a normal operating condition of the electric line is determined by the first signal processing module 5, the third signal processing module 7 does not operate.

The third signal processing module 7 is configured to provide the fourth detection signal V₄, if an abnormal operating condition of the electric line 100 is determined by the first signal processing module 5. Therefore, the third signal processing module 7 provides the fourth detection signal V₄ at time instants following the trigger instant t₀. The fourth detection signal V₄ is obtained by integrating the second detection signal V₂ over time, starting from the trigger instant t₀. As it is the result of the integration of a signal (the second detection signal V₂) indicative of the derivative over time of the line current I, the fourth detection signal V₄ is a signal variable in time depending on the magnitude of the line current I at time instants following the trigger instant t₀. In practice, the fourth detection signal V₄ is indicative the line current I over time, at time instants following the trigger instant t₀.

In some embodiments, the third signal processing module 7 is configured to carry out an integration operation of the second detection signal V₂, if an abnormal operating condition of the electric line 100 is determined by the first signal processing module 5. In this case, the third signal processing module 7 starts operating (from a null-signal level) at the trigger instant t₀ and the fourth detection signal V₄ can be given by the following relation:

$${V}_{4} ( t ) = {\int }_{{t}_{0}}^{t} {V}_{2} ( t ) dt$$

Advantageously, the third signal processing module 7 operates based on second control signals C₂ received from the first signal processing module 5. As an example, the third signal processing module 7 can remain in a stand-by state until it receives a control signal from the first signal processing module 5. In response to receiving a control signal C₂ (trigger signal), which indicates that the first signal processing module 5 has determined that the electric line 100 operates in an abnormal condition (trigger instant t₀, possible transmission delays are substantially negligible), the third signal processing module 7 start carrying out the above-mentioned integration operation (starting from a null signal level).

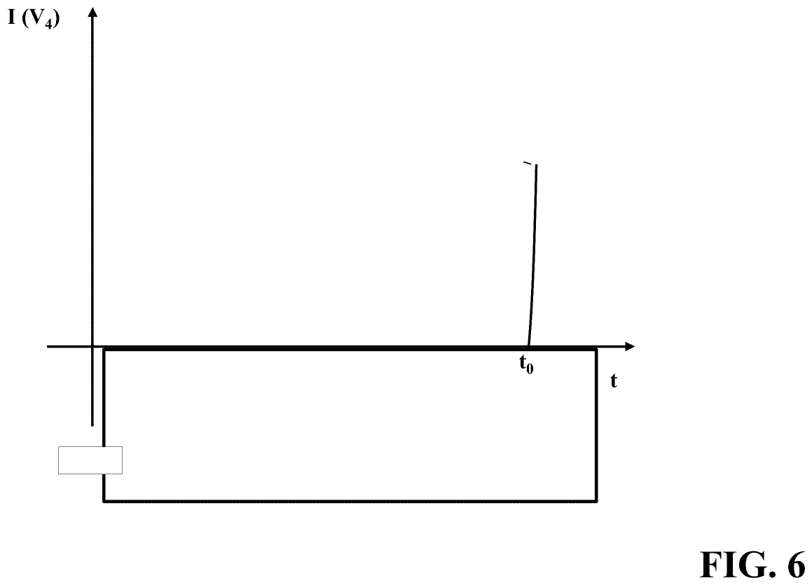

FIG. 6 schematically represents the behavior of the fourth detection signal V₄ as provided by the fourth signal processing module 4. As it is possible to notice, the fourth detection signal V₄ describes the behavior of the line current I at time instants following the trigger instant t₀.

The detection arrangement 1 comprises a fourth signal processing module 8 operatively coupled to the second and third signal processing modules 6, 7 to receive and process the third and fourth detection signals V₃, V₄. The fourth signal processing module 8 is configured to provide in output a fifth detection signal V₅, which is generated based on the above-mentioned detection signals V₃, V₄.

In some embodiments, the fifth detection signal V₅ is a voltage signal in such a way to favor its processing by suitable signal processing resources 10, possibly arranged in cascade to the fourth signal processing module 8. The fourth signal processing module 8 is configured to obtain the fifth detection signal V₅ by carrying out a weighted sum of the above-mentioned third and fourth detection signals V₃, V₄. In practice, the fifth detection signal V₅ can be calculated according to the following relation:

$${V}_{5} ( t ) = {k}_{1} {V}_{3} ( t ) + {k}_{2} {V}_{4} ( t )$$

k₁, k₂ are weight coefficients that can be easily calculated based on the characteristics of the electronics (for example, operational circuits) included in the current detection arrangement and of a threshold current value I_{TH} set to command (trip signal) the interruption of the electric line 100.

Being the result of a weighted sum of the third and fourth detection signals V₃, V₄, the fifth detection signal V₅ is a signal variable in time depending on the magnitude of the line current I. In practice, the fifth detection signal V₅ describes the behavior of the line current I over time.

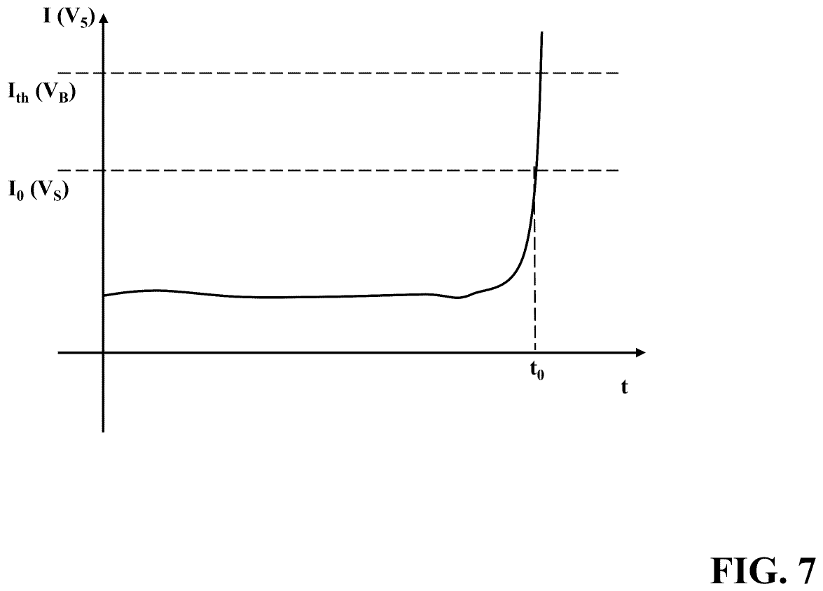

FIG. 7 schematically represents the behavior of the fifth detection signal V₅ as provided by the fourth signal processing module 8. It is possible to notice that at time instants t<=t₀, the fifth detection signal V₅ describes the behavior of the line current I at time instants by virtue of the contribution given by the third detection signal V₃. It is noted that at the instant t=t₀, the fifth detection signal V₅ takes the value V_{S} indicative of the magnitude I₀ of the line current I as measured at the trigger instant t₀. It is also possible to notice that at time instants t>t₀, the fifth detection signal V₅ describes the behavior of the line current I by virtue of the contribution given by the fourth detection signal V₄.

In view of the above, it is apparent that the fifth detection signal V₅ can be expressed by the following relation:

$${V}_{5} ( t ) = {k}_{1} {V}_{3} ( t ) + {k}_{2} {V}_{4} ( t ) = {K}_{1} I ( {t}_{0} ) + {K}_{2} {\int }_{{t}_{0}}^{t} \frac{dI}{dt} ( t ) dt$$

K₁, K₂ are weight coefficients corresponding to the above-mentioned weight coefficients k₁, k₂. The weight coefficients K₁, K₂ can also be easily calculated based on the characteristics of the electronics included in the detection arrangement and the threshold current value I_{TH} set for electric line 100. An example of calculation of the weight coefficients k₁, k₂, K₁, K₂ is proposed in the following.

It is supposed that the electronics of the detection arrangement 1 operates at V_{CC}=±5.0 V and that a threshold current value I_{TH}=4 kA is set to command (trip signal) the interruption of the electric line 100. A threshold voltage value of V₅*=4.7V can be selected for the voltage signal V₅. The threshold voltage value V₅* is the value of the fifth detection signal V₅ (that describes the behavior of the line current I), which corresponds to the above-mentioned threshold current value I_{TH}.

In this case, the weight coefficients K₁, K₂ can be calculated as:

$${K}_{1} = {K}_{2} = {V}_{5} * / {I}_{TH} = 4 , 7 / 4000 = 1 , 175 mv / A .$$

The weight coefficients k₁, k₂ can be calculated based on the weight coefficients K₁, K₂ as:

$${k}_{1} = {k}_{2} = {p}_{1} K 1 = {p}_{2} K 2$$

p₁, p₂ are proportionality factors that depends on the selected threshold current value I_{TH}. As an example, the proportionality factors p₁, p₂ can be calculated as:

$${p}_{1} = {K}_{1} / {G}_{1} = 1 , 175 / 5 = 0 , 235$$

$${p}_{2} = {K}_{2} / {G}_{2} = 1 , 175 / 5 = 0 , 235$$

G₁, G₂ is the gain of the electronics of the detection arrangement 1 for the selected threshold current value I_{TH} (in this case, it is arbitrarily assumed that G₁=G₂=5 mv/A).

As the skilled person can certainly understand, the weight coefficients k₁, k₂, K₁, K₂ can be calculated differently if the electronics included in the current detection arrangement operates differently and a different threshold current value I_{TH} is set to command the interruption of the electric line 100.

As it is possible to notice, the fifth detection signal V₅ can be calculated according to the following relation until a normal condition is determined by the first processing module 3:

$${V}_{5} ( t ) = {k}_{1} {V}_{3} ( t )$$

k₁ is a coefficient that can be easily calculated based on the characteristics of the electronics (for example, operational circuits) included in the current detection arrangement.

In this case, in fact, the third signal processing module 7 is not active (no abnormal condition is detected) and its output signal V₄ is virtually null.

In view of the above, the fifth detection signal V₅ can be expressed by the following relation:

$${V}_{5} ( t ) = {k}_{1} {V}_{3} ( t ) = {K}_{1} I ( t )$$

k₁ is a coefficient corresponding to the above-mentioned coefficient K₁, which may be calculated as shown above.

According to other embodiments of the present disclosure (FIG. 1A), the detection arrangement 1 comprises a fifth signal processing module 9 in addition to the signal processing modules 5, 6, 7, 8 described above with reference to the embodiments of FIG. 1. The fifth signal processing module 9 is operatively coupled to the second detection module 4 to receive and process the second detection signal V₂. The fifth signal processing module 9 is configured to provide and output a sixth detection signal V₆, which is generated based on the second detection signal V₂.

In some embodiments, the sixth detection signal V₆ is a voltage signal to favor its processing by suitable signal processing resources 8, 10 arranged in cascade to the third signal processing module 7. The fifth signal processing module 9 does not provide any detection signal (or a null detection signal), if a normal condition of the electric line 100 is determined by the first signal processing module 5. In practice, if a normal operating condition of the electric line is determined by the first signal processing module 5, the fifth signal processing module 9 does not operate.

The fifth signal processing module 9 is configured to provide the sixth detection signal V₆, if an abnormal operating condition of the electric line 100 is determined by the first signal processing module 5. Therefore, the fifth signal processing module 9 provides the sixth detection signal V₆ at time instants following the trigger instant t₀, at which the first signal processing module 5 has determined that the electric line 100 operates in an abnormal condition. The sixth detection signal V₆ is obtained by rescaling the second detection signal V₂, starting from the trigger instant t₀.

As it results from the amplification of a signal (the second detection signal V₂) indicative of the derivative over time of the line current I, the sixth detection signal V₆ is a signal variable in time depending on the variation rate of the magnitude of the line current I at time instants following the trigger instant t₀. In practice, the sixth detection signal V₆ is indicative of the derivative of the line current I over time, at time instants following the trigger instant t₀.

It is noted that the sixth detection signal V₆ can be considered as taking a constant value, which is indicative of a constant variation rate of the magnitude of the line current I, if the line current I is reasonably considered as a ramp signal at time instants following the trigger instant t₀. Advantageously, the fifth signal processing module 9 operates based on third control signals C₃ received from the first signal processing module 5.

As an example, the fifth signal processing module 9 can remain in a stand-by state until it receives a control signal from the first signal processing module 5. In response to receiving a control signal C₃ (trigger signal), which indicates that the first signal processing module 5 has determined that the electric line 100 operates in an abnormal condition (trigger instant t₀, possible transmission delays are substantially negligible), the fifth signal processing module 9 can start carrying out the above-mentioned amplification functionalities.

According to the embodiment shown in FIG. 1A, the fourth signal processing module 8 of the current detection arrangement is operatively coupled to the second, third and fifth signal processing modules 6, 7, 9 to receive and process the third, fourth and sixth detection signals V₃, V₄, V₆. The fourth signal processing module 8 is configured to provide and output a fifth detection signal V₅, which is generated based on the above-mentioned detection signals V₃, V₄, V₆.

In some embodiments, the fifth detection signal V₅ is a voltage signal. The fourth signal processing module 8 is configured to obtain the fifth detection signal V₅ by carrying out a weighted sum of the above-mentioned third, fourth and sixth detection signals V₃, V₄, V₆.

In practice, the fifth detection signal V₅ can be calculated according to the following relation:

$${V}_{5} ( t ) = {k}_{1} {V}_{3} ( t ) + {k}_{2} {V}_{4} ( t ) + {k}_{0} {V}_{6} ( t ) = {K}_{1} I ( {t}_{0} ) + {K}_{2} {\int }_{{t}_{0}}^{t} \frac{dI}{dt} ( t ) dt + {K}_{0} \frac{dI}{dt} ( t )$$

k₁, k₂, k₀, K₁, K₂, K₀ are weight coefficients corresponding to the above-mentioned weight coefficients k₁, k₂, k₀ that can be easily calculated similarly to the example described above.

As it is possible to notice, the fifth detection signal V₅ can be calculated according to the following relation until a normal condition is determined by the first processing module 3:

$${V}_{5} ( t ) = {k}_{1} {V}_{3} ( t )$$

k₁ is a coefficient that can be easily calculated based on the characteristics of the electronics (for example, operational circuits) included in the current detection arrangement.

In this case, in fact, the third and fifth signal processing modules 7, 9 are not active (no abnormal condition is detected) and their output signals V₄, V₆ are virtually null.

In view of the above, it is apparent that the fifth detection signal V₅ can be expressed by the following relation:

$${V}_{5} ( t ) = {k}_{1} {V}_{3} ( t ) = {K}_{1} I ( t )$$

K₁ is a coefficient corresponding to the above-mentioned coefficient k₁.

In a further aspect, the present disclosure relates to an electronic device 50 for Electric grids. The electronic device 50 may be any kind of IED intended for use in Electric grids, for example a protection relay. The electronic device 50 is configured to drive the operation of a protection device 110 operatively coupled to the electric line 100 to control the flow of a line current I along said electric line. The protection device 110 can take a closed state, at which it allows the flow of the line current I along the electric line, and an open state, at which it allows the flow of the line current I along the electric line.

In some embodiments, the protection device 110 includes one or more solid-state switches and suitable driving electronics to drive said solid-state switches in such a way to cause reversable transitions of the protection device 110 between the above-mentioned operating states. In general, the protection device 110 can be of the known type and it will here not be disclosed in further details for the sake of brevity. As an example, the protection device 110 can be a circuit breaker of the solid-state type or a circuit breaker of the hybrid type.

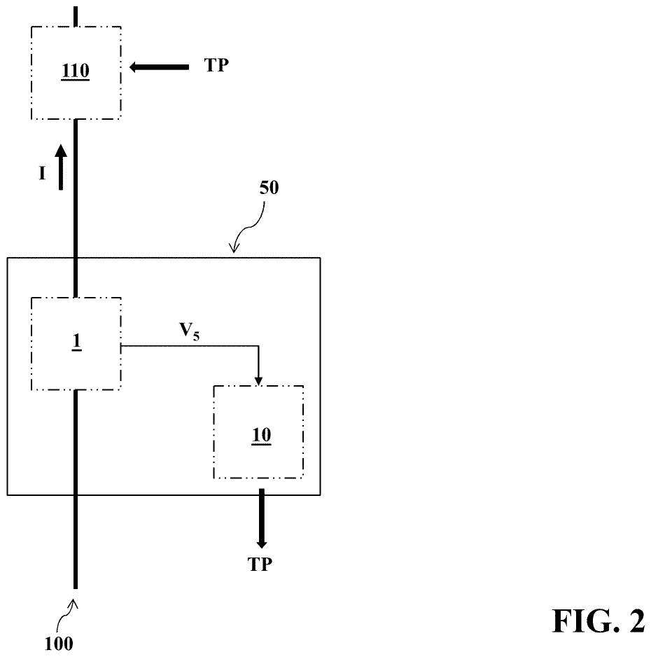

According to some embodiments (FIG. 2), the electronic device 50 includes the detection arrangement 1 of the present disclosure as described above.

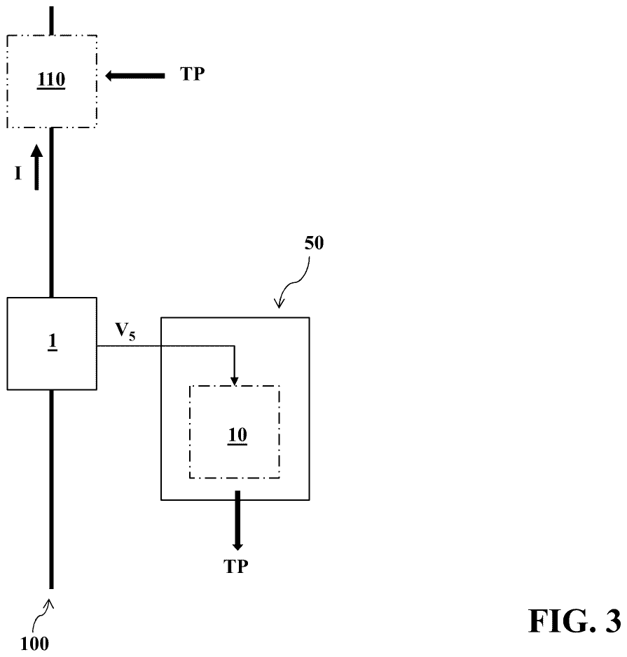

According to other embodiments (FIG. 3), the electronic device 50 is operatively coupled to the current detection arrangement 1 of the present disclosure as described above.

In some embodiments, the electronic device 50 includes a signal processing stage 10 operatively coupled to the fourth signal processing module 8 of the current detection arrangement to receive and process the fifth detection signal V₅ output provided by said signal processing module.

In some embodiments, the signal processing stage 10 is configured to provide a trip signal TP for the protection device 110, in particular to command a transition of the latter from a closed state to an open state. The signal processing stage 10 is configured to generate the trip signal TP based on the fifth detection signal V₅ provided by the fourth signal processing module 8 of the current detection arrangement.

In some embodiments, the signal processing stage 10 is configured to compare the fifth detection signal V₅ with a second threshold value V_{B} indicative of a threshold current value I_{TH} set to command the interruption of the line current I flowing along the electric line (FIG. 7).

In some embodiments, the signal processing stage 10 is configured to provide and output the above-mentioned trip signal TP, if the fifth detection signal V₅ exceeds the second threshold value V_{B}.

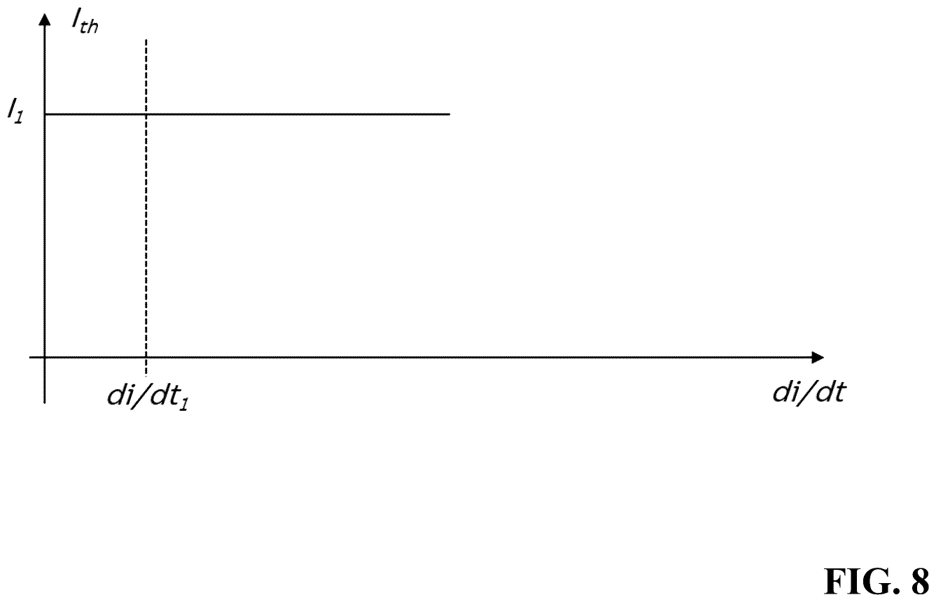

According to an embodiment of the electronic device 50, the threshold current value I_{TH} is constant, and it does not vary with the derivative dI/dt of the line current I. FIG. 8 shows as example of a tripping curve set for the switching device 110 in accordance with this solution. As it is possible to notice, the threshold current value is set to I_{TH}=I₁ and it does not vary with the derivative dI/dt of the line current I.

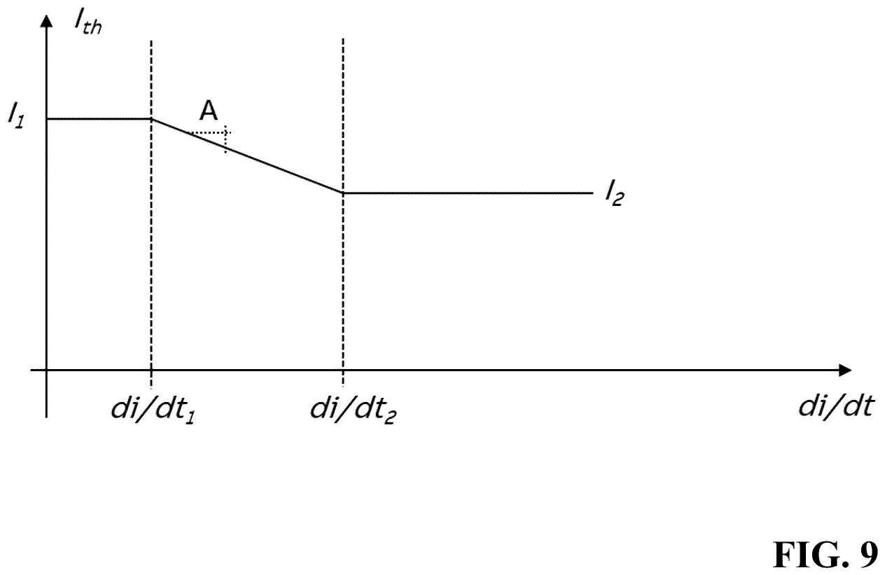

According to another embodiment of the electronic device 50, the threshold current value I_{TH} can vary with the derivative dI/dt of the line current I. FIG. 9 shows an example of a tripping curve set for the switching device 110 in accordance with this solution. As it is possible to notice, the threshold current value is set to a first constant value I_{TH}=I₁, if the derivative of the line current I is lower than a first predefined derivative value dI/dt₁, which, in some embodiments, coincides with the threshold variation rate dI/dt* of the line current at the above-mentioned trigger instant t₀ (FIG. 4). The threshold current is also set to a second constant value I_{TH}=12<I₁, if the derivative of the line current I is higher than a second predefined derivative value dI/dt₂. Additionally, the threshold current is set to a value variable with the derivative of the line current I for derivative values included in the range of values dI/dt₁<=dI/dt<=dI/dt₂. In this case, the threshold current value I_{TH} may belong to a line having a (negative) slope A=(I₂−I₁)/(dI/dt₂−dI/dt₁).

This kind of tripping curve is particularly useful to drive a switching device 110 including solid-state switches (for example IGBTs) with a relatively high turn-off delay. In this case, it is safer to set the threshold current I_{TH} at a lower level, when the line current I raises very fast (dI/dt>=dI/dt₂) On the other, the threshold current I_{TH} can be set at a higher level, when the line current I raises slowly (dI/dt<=dI/dt₁).

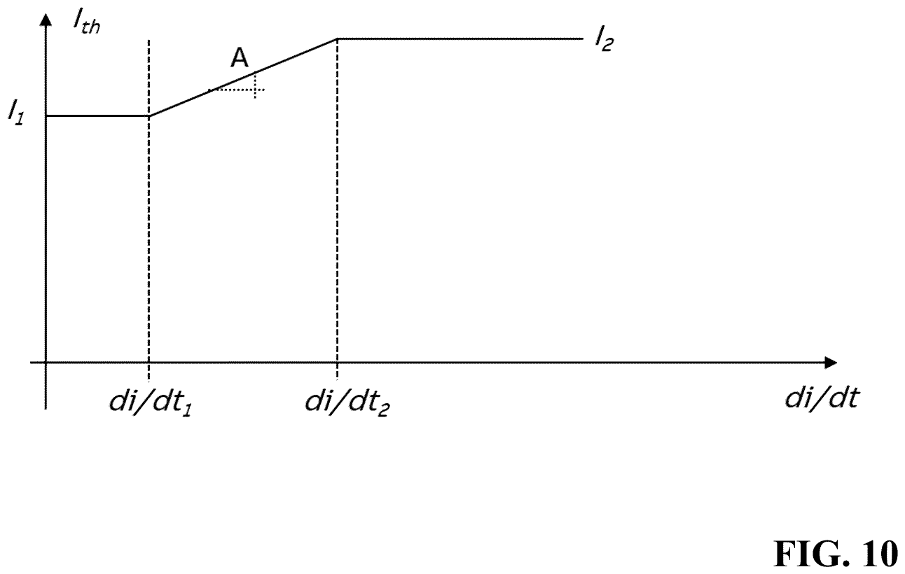

FIG. 10 shows another example of a tripping curve set for the switching device 110 in accordance with the above-mentioned solution. As it is possible to notice, the threshold current I_{TH} is set to a first constant value I_{TH}=11, if the derivative of the line current I is lower than a first predefined derivative value dI/dt₁, which, in some embodiments, coincides with the threshold variation rate dI/dt* of the line current at the above-mentioned trigger instant t₀ (FIG. 4). The threshold current is also set to a second constant value I_{TH}=12>I₁, if the derivative of the line current I is higher than a second predefined derivative value dI/dt₂. Additionally, the threshold current is set to a value variable with the derivative of the line current I for derivative values included in the range of values dI/dt₁<=dI/dt<=dI/dt₂. In this case, the threshold current value I_{TH} may belong to a line having a (positive) slope A=(I₂−I₁)/(dI/dt₂−dI/dt₁).

This kind of tripping curve is particularly useful to drive a protection device 110 including solid-state switches (for example MOSFETs) with a relatively small turn-off energy capability. In this case, it is safer to set the threshold current I_{TH} at a lower level, when the line current I raises slowly (dI/dt<=dI/dt₁). On the other, the threshold current I_{TH} can be set at a higher level, when the line current I raises fast (dI/dt>=dI/dt₂).

In these last embodiments of the electronic device 50, the most appropriate threshold current value I_{TH} value (in consideration of the characteristics of the solid-state switches of the protection device 110) can be dynamically selected based on the detection information provided by the detection arrangement 1. Such a detection information includes, in general, the fifth detection signal V₅ provided by the fourth signal processing module 8. More particularly, said detection information includes the second detection signal V₂ provided by the second detection module 4 and based on the sixth detection signal V₆ provided by the fifth signal processing module 9. In practice, it has been found that the detection arrangement, according to the present disclosure, fully achieves the intended aim and objects.

The detection arrangement 1 can determine whether the electric line 100 is operating in a normal or an abnormal condition by acquiring a detection signal V₂ indicative the derivative of the line current I flowing along the electric line. The detection arrangement 1 is thus capable of detecting quick changes in the operating condition of the electric line by exploiting the information provided by the high bandwidth signal V₂.

When the electric line 100 operates in a normal condition (time instants preceding the above-mentioned trigger instant t₀), the detection arrangement 1 behaves substantially as a traditional current detection arrangement. In this case, in fact, the line current I is subject to smooth variations about its nominal value and it can be monitored in a traditional way without particular issues.

When the electric line 100 instead operates in an abnormal condition (time instants following the above-mentioned trigger instant t₀), the detection arrangement 1 processes the detection signal V₂ indicative of the derivative of the line current I to reconstruct the behavior of the line current itself. The reconstruction of the line current I is conveniently carried out through simple and quick signal processing techniques (computation time is in the order of ms or lower), which allows a reliable detection of the line current I even if the latter is raising very fast, for example with magnitude variation rates in the order of 1000 A/ms. The detection arrangement 1, according to the present disclosure, therefore, allows an effective monitoring of the line current I in any operating conditions of the electric line 100.

According to some embodiments of the present disclosure, the detection information provided by the detection arrangement 1 can be suitably exploited to dynamically select the threshold current I_{TH} to be used as a reference to command the interruption of the line current I flowing along the electric line 100. In this way, it is possible to trip the protection device 110 operatively coupled to the electric line 100 in the most appropriate ways to ensure a reliable circuit protection and, at the same time, prevent unnecessary service interruptions. The detection arrangement has a compact structure. It is relatively easy to manufacture at industrial scale and can be produced at competitive costs compared with currently available state of the art solutions.

The disclosed systems and methods are not limited to the specific embodiments described herein. Rather, components of the systems or activities of the methods may be utilized independently and separately from other described components or activities.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1. A current detection arrangement for electric grids, the current detection arrangement comprising:
a first detection module operatively coupled to an electric line and configured to provide a first detection signal indicative of a line current flowing along the electric line;
a second detection module operatively coupled to the electric line and configured to provide a second detection signal indicative of a variation rate over time of the line current;
a first signal processing module operatively coupled to the second detection module the first signal processing module configured to receive and process the second detection signal, wherein the first signal processing module is configured to determine an operating condition of the electric line based on the second detection signal, and wherein the first signal processing module is configured to provide control signals for other signal processing modules, the control signals being generated depending on the determined operating condition of the electric line;
a second signal processing module operatively coupled to the first detection module the second signal processing module configured to receive and process the first detection signal, wherein the second signal processing module is configured to provide a third detection signal tracking the first detection signal, if a normal operating condition of the electric line is determined by the first signal processing module, and wherein the second signal processing module is configured to provide the third detection signal having a constant value, if an abnormal operating condition of the electric line is determined by the first signal processing module, the constant value being indicative of a magnitude value of the line current measured at a trigger instant, at which the first signal processing module has determined that the electric line operates in an abnormal condition;
a third signal processing module operatively coupled to the second detection module the third signal processing module configured to receive and process the second detection signal, wherein the third signal processing module is configured to provide a fourth detection signal indicative of the line current, if an abnormal operating condition of the electric line is determined by the first signal processing module, wherein the first signal processing module is configured to provide the fourth detection signal at time instants following the trigger instant, and wherein the third signal processing module is configured to obtain the fourth detection signal by integrating over time the second detection signal; and
a fourth signal processing module operatively coupled to the second and third signal processing modules, the fourth signal processing module configured to receive and process the third and fourth detection signals, wherein the fourth signal processing module is configured to provide a fifth detection signal indicative of the line current, and wherein the fourth signal processing module is configured to obtain the fifth detection signal by carrying out a weighted sum of the third and fourth detection signals.

2. The current detection arrangement according to claim 1, wherein the first detection module comprises a first sensing block including one or more Hall-effect sensors or one or more shunt resistors.

3. The current detection arrangement according to claim 2, wherein the first detection module includes a first filtering block electrically connected in cascade to the first sensing block.

4. The current detection arrangement according to claim 1, wherein the second detection module comprises a second sensing block including at least a Rogowski coil.

5. The current detection arrangement according to claim 4, wherein the first detection module includes a second filtering block electrically connected in cascade to the second sensing block.

6. The current detection arrangement according to claim 1, wherein one of the previous claims, characterized in that the first signal processing module is configured to:
compare the second detection signal with a first threshold value indicative of a predefined threshold variation rate of the line current;
determine that the electric line operates in a normal condition, if the second detection signal does not exceed the first threshold value; and
determine that the electric line operates in an abnormal condition, if the second detection signal exceeds the first threshold value.

7. The current detection arrangement according to claim 1, further comprising a fifth signal processing module operatively coupled to the second detection module, the fifth signal processing module configured to receive and process the second detection signal, wherein:
the fifth signal processing module is configured to provide a sixth detection signal indicative of a variation rate over time of the line current, if an abnormal operating condition of the electric line are determined by the first signal processing module,
the fifth signal processing module is configured to provide the sixth detection signal at time instants following the trigger instant, and
the third signal processing module is configured to obtain the sixth detection signal by amplifying the second detection signal.

8. The current detection arrangement according to claim 7, wherein the fifth signal processing module is operatively coupled to the second, third and sixth signal processing modules, and wherein:
the fifth signal processing module is configured to receive and process the third, fourth and sixth detection signals,
the fourth signal processing module is configured to provide the fifth detection signal indicative of the line current, and
the fourth signal processing module is configured to obtain the fifth detection signal by carrying out a weighted sum of the third, fourth and sixth detection signals.

9. The current detection arrangement according to claim 1, wherein the electric line is a DC electric line.

10. An electronic device for electric grids including or operatively coupled to a detection arrangement, the detection arrangement comprising:
a first detection module operatively coupled to an electric line and configured to provide a first detection signal indicative of a line current flowing along the electric line;
a second detection module operatively coupled to the electric line and configured to provide a second detection signal indicative of a variation rate over time of the line current;
a first signal processing module operatively coupled to the second detection module the first signal processing module configured to receive and process the second detection signal, wherein the first signal processing module is configured to determine an operating condition of the electric line based on the second detection signal, and wherein the first signal processing module is configured to provide control signals for other signal processing modules, the control signals generated depending on the determined operating condition of the electric line;
a second signal processing module operatively coupled to the first detection module the second signal processing module configured to receive and process the first detection signal, wherein the second signal processing module is configured to provide a third detection signal tracking the first detection signal, if a normal operating condition of the electric line is determined by the first signal processing module, and wherein the second signal processing module is configured to provide the third detection signal having a constant value, if an abnormal operating condition of the electric line is determined by the first signal processing module, the constant value indicative of a magnitude value of the line current measured at a trigger instant, at which the first signal processing module has determined that the electric line operates in an abnormal condition;
a third signal processing module operatively coupled to the second detection module the third signal processing module configured to receive and process the second detection signal, wherein the third signal processing module is configured to provide a fourth detection signal indicative of the line current, if an abnormal operating condition of the electric line is determined by the first signal processing module, wherein the first signal processing module is configured to provide the fourth detection signal at time instants following the trigger instant, and wherein the third signal processing module is configured to obtain the fourth detection signal by integrating over time the second detection signal; and
a fourth signal processing module operatively coupled to the second and third signal processing modules, the fourth signal processing module configured to receive and process the third and fourth detection signals, wherein the fourth signal processing module is configured to provide a fifth detection signal indicative of the line current, and wherein the fourth signal processing module is configured to obtain the fifth detection signal by carrying out a weighted sum of the third and fourth detection signals.

11. The electronic device according to claim 10, further comprising a signal processing stage operatively coupled to the fourth signal processing module of the detection arrangement, the signal processing stage configured to receive and process the fifth detection signal, wherein the signal processing stage is configured to provide a trip signal for a protection device operatively coupled to the electric line, the trip signal generated based on the fifth detection signal.

12. The electronic device according to claim 11, wherein the signal processing stage is further configured to:
compare the fifth detection signal with a second threshold value indicative of a threshold current value set to command interruption of a line current flowing along the electric line; and
provide the trip signal, if the fifth detection signal exceeds the second threshold value.

13. The electronic device, according to claim 12, wherein the threshold current value is predefined.

14. The electronic device, according to claim 12, wherein the threshold current value is variable with a derivative of the line current flowing along the electric line, the threshold current value dynamically set based on detection information provided by the detection arrangement.

15. A protection device for electric grids including or operatively coupled to an electronic device, the electronic device including or operatively coupled to a detection arrangement, the detection arrangement comprising:
a first detection module operatively coupled to an electric line and configured to provide a first detection signal indicative of a line current flowing along the electric line;
a second detection module operatively coupled to the electric line and configured to provide a second detection signal indicative of a variation rate over time of the line current;
a first signal processing module operatively coupled to the second detection module the first signal processing module configured to receive and process the second detection signal, wherein the first signal processing module is configured to determine an operating condition of the electric line based on the second detection signal, and wherein the first signal processing module is configured to provide control signals for other signal processing modules, the control signals generated depending on the determined operating condition of the electric line;
a second signal processing module operatively coupled to the first detection module the second signal processing module configured to receive and process the first detection signal, wherein the second signal processing module is configured to provide a third detection signal tracking the first detection signal, if a normal operating condition of the electric line is determined by the first signal processing module, and wherein the second signal processing module is configured to provide the third detection signal having a constant value, if an abnormal operating condition of the electric line is determined by the first signal processing module, the constant value indicative of a magnitude value of the line current measured at a trigger instant, at which the first signal processing module has determined that the electric line operates in an abnormal condition;
a third signal processing module operatively coupled to the second detection module the third signal processing module configured to receive and process the second detection signal, wherein the third signal processing module is configured to provide a fourth detection signal indicative of the line current, if an abnormal operating condition of the electric line is determined by the first signal processing module, wherein the first signal processing module is configured to provide the fourth detection signal at time instants following the trigger instant, and wherein the third signal processing module is configured to obtain the fourth detection signal by integrating over time the second detection signal; and
a fourth signal processing module operatively coupled to the second and third signal processing modules, the fourth signal processing module configured to receive and process the third and fourth detection signals, wherein the fourth signal processing module is configured to provide a fifth detection signal indicative of the line current, and wherein the fourth signal processing module is configured to obtain the fifth detection signal by carrying out a weighted sum of the third and fourth detection signals, according to one of the claims from 10 to 14.

16. The protection device according to claim 15, wherein the protection device comprises a circuit breaker of a solid-state type or a hybrid type, and wherein the circuit breaker includes one or more solid-state switches.

17. The electronic device according to claim 10, wherein the first detection module comprises a first sensing block including one or more Hall-effect sensors or one or more shunt resistors.

18. The electronic device according to claim 10, wherein the second detection module comprises a second sensing block including at least a Rogowski coil.

19. The protection device according to claim 15, wherein the first detection module comprises a first sensing block including one or more Hall-effect sensors or one or more shunt resistors.

20. The protection device according to claim 15, wherein the second detection module comprises a second sensing block including at least a Rogowski coil.
